(19) United States
(12) Patent Application Publication
(10) Pub. No.: US 2015/0372207 A1
(43) Pub. Date: Dec. 24, 2015

(54) SEMICONDUCTOR LIGHT EMITTING DEVICE PACKAGE

(71) Applicants: Kyoung Jun KIM, Yongin-si (KR); Yong Min KWON, Seoul (KR)

(72) Inventors: Kyoung Jun KIM, Yongin-si (KR); Yong Min KWON, Seoul (KR)

(21) Appl. No.: 14/644,174

(22) Filed: Mar. 10, 2015

(30) Foreign Application Priority Data
Jun. 24, 2014 (KR) 10-2014-0077242

(51) Int. Cl. H01L 33/62; H01L 33/56; H01L 33/36; H01L 33/50

(52) U.S. Cl. CPC H01L 33/62; H01L 33/507; H01L 33/56; H01L 33/36

(57) ABSTRACT

A semiconductor light emitting device package includes a semiconductor laminate having first and second surfaces and side surfaces, and including first and second conductivity-type semiconductor layers, and an active layer, a support body disposed on the second surface and including first and second package electrodes, a first electrode layer disposed on the first surface and connected to the first conductivity-type semiconductor layer and extended along a side of the semiconductor laminate to be connected to the first package electrode, a side insulating layer disposed on a side of the semiconductor laminate and electrically insulating the first electrode layer from the side of the semiconductor laminate, and a second electrode layer disposed on the second surface and electrically connecting the first conductivity-type semiconductor layer to the second package electrode.

### CROSS-REFERENCE TO RELATED APPLICATION

This application claims the priority to Korean Patent Application No. 10-2014-0077242 filed on Jun. 24, 2014, with the Korean Intellectual Property Office, the disclosure of which is incorporated herein by reference.

### BACKGROUND

The present disclosure relates to a semiconductor light emitting device package.

Light emitting diodes (LED) are extensively used as light sources, due to several positive attributes thereof, such as low power consumption, high luminance, and the like. In particular, recently, light emitting devices using LEDs have been employed in general lighting devices and in the backlight units of large-sized liquid crystal displays. Such light emitting devices are provided in the form of packages, facilitating the installation thereof in various apparatuses. As the use of LEDs has been extended into a variety of areas for lighting, packages are required to be decreased in the size for the degree of freedom in an illumination design so as to be appropriate for respective usages.

Further, in light emitting device packages, as the amounts of current applied thereto have increased, heat dissipation for discharging heat generated in light emitting devices has emerged as an important issue in packages used in areas for high-output light emitting devices such as general lighting devices and large-sized backlight units.

### SUMMARY

An aspect of the present disclosure relates to a semiconductor light emitting device package having a novel structure having improved heat dissipation characteristics and a simplified process.

According to an example embodiment, a semiconductor light emitting device package may include a semiconductor laminate having a first surface and a second surface disposed to oppose each other, and a side surface between the first and second surfaces, and including a first conductivity-type semiconductor layer and a second conductivity-type semiconductor layer forming the first surface and the second surface, respectively, and an active layer disposed between the first and second conductivity-type semiconductor layers, a support body disposed on the second surface of the semiconductor laminate and including a first package electrode and a second package electrode, a first electrode layer disposed on the first surface of the semiconductor laminate to be connected to the first conductivity-type semiconductor layer and extended along the side surface of the semiconductor laminate to be connected to the first package electrode, a side insulating layer disposed on the side surface of the semiconductor laminate and electrically insulating the first electrode layer from the side of the semiconductor laminate, and a second electrode layer disposed on the second surface of the semiconductor laminate and electrically connecting the first conductivity-type semiconductor layer to the second package electrode.

The first package electrode may have a contact region located on an edge of the support body, and the contact region is connected to the first electrode layer. The contact region may include a descending part descending to be lower than a level of the other part of the first package electrode.

The first package electrode may encompass at least a portion of the second package electrode. Conversely, the first package electrode and the second package electrode may be arrayed to be substantially parallel to each other.

The first package electrode and the second package electrode may be separated from each other by an air gap. The second package electrode may have a cross sectional area, greater than that of the first package electrode.

The semiconductor light emitting device package may further include an insulating film disposed at least in a region, in which the second electrode layer is not formed, among the second surface of the semiconductor laminate.

A region in which the second electrode layer is formed may occupy 50% or more of an overall area of the second surface.

The side surface of the semiconductor laminate may have an inclined plane.

The semiconductor light emitting device package may further include a resin encapsulation unit disposed to encompass the semiconductor laminate. In this case, a side of the resin encapsulation unit may have a surface substantially coplanar with a side surface of the support body. A portion of the first electrode layer may be disposed between the resin encapsulation unit and the support body and may be exposed to the surface substantially coplanar with the side surface of the support body.

The semiconductor light emitting device package may further include a wavelength conversion layer disposed on at least the first surface of the semiconductor laminate.

The first electrode layer may include a transparent electrode layer. The first electrode layer may include a transparent electrode layer disposed on the first surface of the semiconductor laminate and a metal electrode layer disposed along the side surface of the semiconductor laminate to connect the transparent electrode layer and the first package electrode to each other. The first electrode layer may include a plurality of electrode fingers disposed on the first surface of the semiconductor laminate.

According to an example embodiment, a semiconductor light emitting device package may include a semiconductor laminate having a first surface and a second surface disposed to oppose each other, and a side surface between the first and second surfaces, and including a first conductivity-type semiconductor layer and a second conductivity-type semiconductor layer forming the first surface and the second surface, respectively, and an active layer disposed between the first and second conductivity-type semiconductor layers, a second electrode layer disposed on a first region of the second surface of the semiconductor laminate and connected to the second conductivity-type semiconductor layer, an insulating film disposed in a second region of the second surface of the semiconductor laminate and formed of an electrically insulating material, a first package electrode disposed on the insulating film and having a contact region adjacent to an edge of the second surface of the semiconductor laminate, a second package electrode disposed on the second surface of the semiconductor laminate and connected to the second electrode layer, and a first electrode layer connecting the first conductivity-type semiconductor layer to the contact region of the first package electrode.

The contact region may include a descending part descending to be lower than a level of the remaining part of the first package electrode.

The semiconductor laminate may have an inclined side surface, and the first electrode layer may be extended along the inclined side surface of the semiconductor laminate from the first surface, to be connected to the contact region.

A portion of the second package electrode may contact the insulating film. The semiconductor light emitting device package may further include an insulating member disposed between the first and second package electrodes to connect the first and second package electrodes to each other.

The semiconductor light emitting device package may further include a resin encapsulation unit encompassing the semiconductor laminate, a side of the resin encapsulation unit may have a surface substantially coplanar with side surfaces of the first and second package electrodes.

According to an example embodiment, a lighting device may include the semiconductor light emitting device package described above, a driving unit configured to drive the semiconductor light emitting device package, and an external connection unit configured to supply an external voltage to the driving unit.

According to an example embodiment of the present invention, a semiconductor light emitting device package may include a support body and a semiconductor laminate formed on the support body. The semiconductor laminate may include first and second conductivity-type semiconductor layers, and an active layer interposed between the first and second conductivity-type semiconductor layers. A side surface of the semiconductor laminate may terminate the first and second conductive-type semiconductor layers and the active layer. The first conductivity-type semiconductor layer and the support body may be electrically connected to each other via a portion of a first electrode layer formed on the side surface.

The support body may include first and second package electrodes electrically isolated from each other. The first electrode layer may be electrically connected to the first package electrode, and the second conductive-type semiconductor layer may be electrically connected to the second package electrode.

The semiconductor light emitting device package may further include a side insulating layer disposed between the portion of the first electrode layer and the second conductive-type semiconductor layer.

The first electrode layer may include another portion covering the first conductive-type semiconductor layer. The first conductive-type semiconductor layer may be interposed between the active layer and the other portion of the first electrode layer.

The semiconductor light emitting device package may further include a second electrode layer interposed between the second conductive-type semiconductor layer and the second package electrode.

The semiconductor light emitting device package may further include an insulating film disposed between the second conductive-type semiconductor layer and the first package electrode.

The second package electrode may physically contact the insulating film.

The first electrode may extend to a recess formed in the support body.

The first electrode may be terminated by a plane coplanar with a side surface of the support body.

The side surface of the semiconductor laminate may have an inclined plane with respect to a side surface of the support body.

The semiconductor light emitting device package may further include a resin encapsulation unit encompassing the semiconductor laminate.

The semiconductor light emitting device package may further include a wavelength conversion layer covering the semiconductor laminate.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a side cross-sectional view of a semiconductor light emitting device package according to an exemplary embodiment;

FIGS. 2 and 3 illustrate an upper plan view and a bottom view of the semiconductor light emitting device package of FIG. 1, respectively;

FIG. 4 is a plan view of a wafer provided with semiconductor laminates formed therein;

FIGS. 5 to 13 are cross-sectional views illustrating respective main processes of a method of manufacturing a semiconductor light emitting device package illustrated in FIG. 1, according to an exemplary embodiment of the present invention;

FIG. 14 is a side cross-sectional view of a semiconductor light emitting device package according to another exemplary embodiment of the present invention;

FIGS. 15 and 16 are a top plan view and a bottom view of a semiconductor light emitting device package of FIG. 14, respectively;

FIG. 17 is a schematic view of a support body employed in a semiconductor light emitting device package according to an exemplary embodiment of the present invention;

FIG. 18 is a top plan view of a semiconductor light emitting device package according to an exemplary embodiment of the present invention;

FIGS. 19 and 20 illustrate examples of a backlight unit to which a semiconductor light emitting device package according to an exemplary embodiment is applied;

FIG. 21 illustrates an example of a lighting device in which a semiconductor light emitting device package according to an exemplary embodiment is employed; and

FIG. 22 illustrates an example of a headlamp in which a semiconductor light emitting device package according to an exemplary embodiment is employed.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted. The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. Unless explicitly described otherwise, the terms ‘upper part’, ‘upper surface’, ‘lower part’, ‘lower surface’, ‘side surface’, and the like will be used, based on the drawings, and may be changed depending on a direction in which a semiconductor device is disposed.

In the drawings, the shapes and dimensions of elements may be exaggerated for clarity, and the same reference numerals will be used throughout to designate the same or like elements.

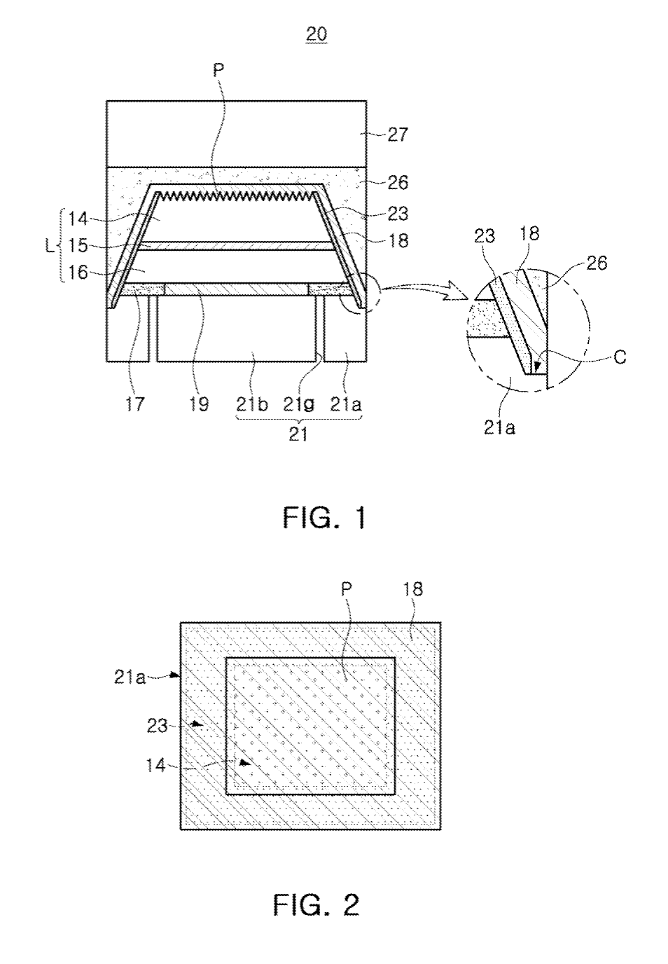

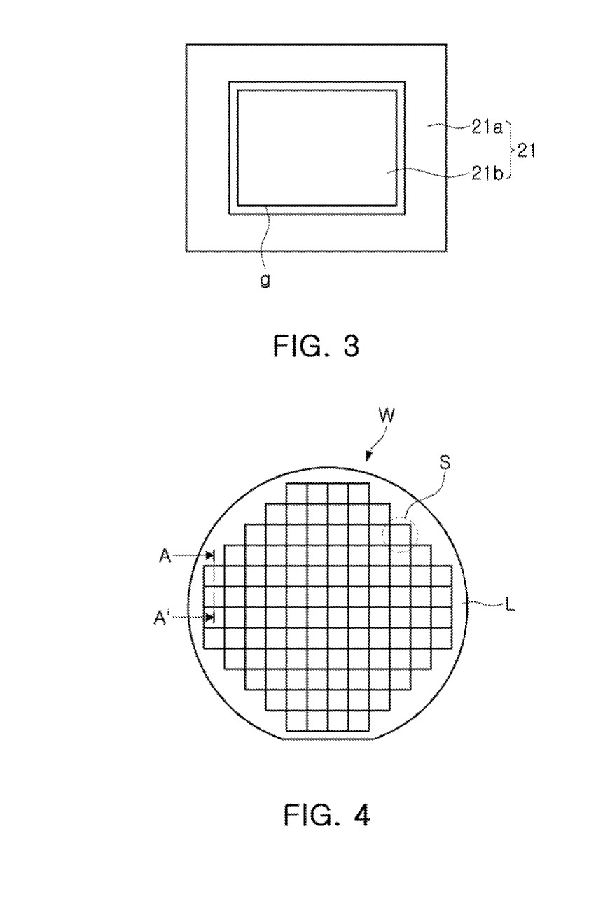

FIG. 1 is a schematic cross-sectional view of a semiconductor light emitting device package according to an exemplary embodiment of the present invention, and FIGS. 2 and 3 illustrate an upper plan view and a bottom view of the semiconductor light emitting device package of FIG. 1, respectively.

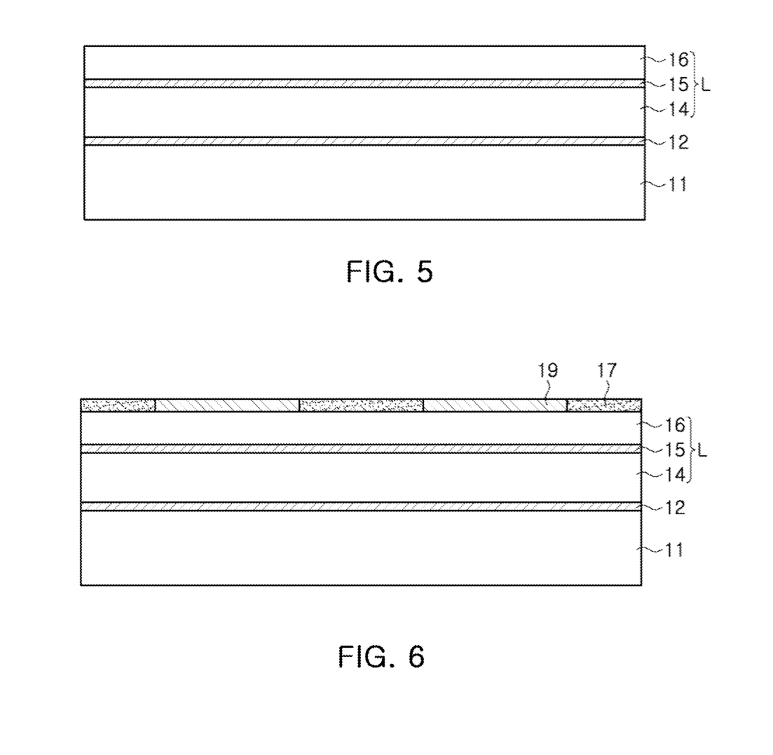

With reference to FIG. 1, a semiconductor light emitting device package 20 may include a semiconductor laminate L, a support body 21, a wavelength conversion layer 26 encompassing the semiconductor laminate L, and a resin encapsulation unit 27. The semiconductor light emitting device package 20 according to the exemplary embodiment may be a chip scale package (CSP). Such a package as the semiconductor light emitting device package 20 may be obtained through a wafer level package (WLP) process which will be discussed later with reference to FIGS. 5 to 13.

The semiconductor laminate L may include a first conductivity-type semiconductor layer 14, a second conductivity-type semiconductor layer 16, and an active layer 15 disposed therebetween. The semiconductor laminate L may have a first surface and a second surface formed by the first and second conductivity-type semiconductor layers 14 and 16, respectively, the second surface opposing the first surface, and side surfaces disposed therebetween.

The semiconductor laminate L may be a nitride semiconductor satisfying AlₓIn_{y}Ga_{1-x-y}N (0≦x≦1, 0≦y≦1, and 0≦x+y≦1). The first and second conductivity-type semiconductor layers 14 and 16 configuring the semiconductor laminate L may be a p-type semiconductor layer and an n-type semiconductor layer, respectively, but are not limited thereto. The first and second conductivity-type semiconductor layers 14 and 16 may be single layers, but may have multilayer structure in which a composition and/or a doping concentration of impurities is different. For example, the first conductivity-type semiconductor layer 14 may be an n-type GaN layer and the second conductivity-type semiconductor layer 16 may be a p-type AlGaN/p-type GaN layer. The active layer 15 may be configured to generate a specific wavelength of light through the recombination of electrons and holes supplied from the first and second conductivity-type semiconductor layers 14 and 16. For example, the active layer 15 may have a multiple quantum well (MQW) structure in which quantum well layers and quantum barrier layers are alternately stacked on top of each other. When the semiconductor laminate L is a nitride semiconductor, the active layer 15 may have a GaN/InGaN the MQW structure. However, the present disclosure is not limited thereto. The active layer 15 may have a single quantum well (SQW) structure as needed. According to other embodiments of the present invention, the semiconductor laminate L may be formed using a semiconductor material having a different composition. For example, in addition to the nitride semiconductor, an AlInGaP or AlInGaAs-based semiconductor may also be used.

In the case of the semiconductor laminate L, the semiconductor laminate L may be obtained after growth thereof on a separate growth substrate and then being transferred to the support body 21. The growth substrate may be removed from the semiconductor laminate L, and an exposed surface, for example, the first surface of the semiconductor laminate L, from which the growth substrate has been removed, may have a concave-convex portion P formed therein so as to improve light extraction efficiency. The concave-convex portion P may be obtained by applying wet etching or dry etching by using plasma to a surface of the first conductivity-type semiconductor layer 14 after removing the growth substrate from the semiconductor laminate L or during the process thereof.

A side insulating layer 23 may be formed on the side surface of the semiconductor laminate L. As illustrated in FIG. 1, the side insulating layer 23 may be disposed on the entirety of the side surface of the semiconductor laminate L to be provided as a passivation layer thereon. The side insulating layer 23 may be a silicon oxide or silicon nitride layer. The side surface of the semiconductor laminate L may be inclined to facilitate deposition of the side insulating layer 23 thereon.

According to the exemplary embodiment, a first electrode layer 18 and a second electrode layer 19 may be connected to the first conductivity-type semiconductor layer 14 and the second conductivity-type semiconductor layer 16 through the first surface and the second surface of the semiconductor laminate L, respectively. As such, since two electrodes 18 and 19 are disposed on the first and second surfaces of the semiconductor laminate, respectively, a relatively high degree of uniform current distribution may be promoted on the semiconductor laminate L, in detail, in terms of the overall area of the active layer.

Unlike such an exemplary embodiment, for example, in a case in which the first conductivity-type semiconductor layer 14 is connected to a first package electrode 21a on the second surface of the semiconductor laminate L, an etching process to expose the first conductivity-type semiconductor layer 14 may be required to be performed on the second surface. Thus, such an etching process may partially remove the active layer 15 to reduce a light emission area. In addition, in such a structure, since a relatively large-sized step portion may be formed due to, for example, a via hole or mesa etching, in a region to which the first conductivity-type semiconductor layer 14 is exposed, voids may occur therein at the time of bonding the semiconductor laminate L to the support body 21 such that junction defects may occur.

On the other hand, in the exemplary embodiment, the first electrode layer 18 connected to the first conductivity-type semiconductor layer 14 through the first surface of the semiconductor laminate L may be extended along the side surface of the semiconductor laminate L and may be connected to the first package electrode 21a disposed on the second surface. In such a structure, since an additional etching process of the semiconductor laminate L may not be required, a light emission area may be maintained, and a step portion on a junction surface, for example, the second surface of the semiconductor laminate L, may be reduced, such that a relatively high degree of bonding strength between the semiconductor laminate L and the support body 21 may be secured.

The first electrode layer 18 may include a transparent electrode. Although the entirety of the first electrode layer 18 may be formed of a transparent electrode as in the exemplary embodiment, a region thereof connected to the first surface of the semiconductor laminate L may be formed of a transparent electrode, and the remaining region may be formed of a metal electrode, as needed. The transparent electrode according to the exemplary embodiment may be one of a transparent conductive oxide layer or nitride layer, but is not limited thereto. For example, the transparent electrode may be one or more selected from a group consisting of indium tin oxide (ITO), zinc-doped indium tin oxide (ZITO), zinc indium oxide (ZIO), gallium indium oxide (GIO), zinc tin oxide (ZTO), fluorine-doped tin oxide (FTC)), aluminum-doped zinc oxide (AZO), gallium-doped zinc oxide (GZO), and In₄Sn₃O₁₂ or Zn₍₁₋ₓ₎MgₓO (Zinc Magnesium Oxide, 0≦x≦1). The first electrode layer 18 may contain grapheme as necessary.

The second electrode layer 19 may be formed on the second surface of the semiconductor laminate L. The second electrode layer 19 may be formed using an ohmic contact material having a relatively high degree of reflectivity. For example, the second electrode layer 19 may contain a material such as Ag, Ni, Al, Rh, Pd, Ir, Ru, Mg, Zn, Pt, Au, and the like, and may have a two or more layer structure of Ni/Ag, Zn/Ag, Ni/Al, Zn/Al, Pd/Ag, Pd/Al, Ir/Ag. Ir/Au, Pt/Ag, Pt/Al, or Ni/Ag/Pt.

According to the exemplary embodiment, although the exemplary embodiment illustrates that the first electrode layer 18 and the second electrode layer 19 respectively have one layer, a plurality of electrode layers may be formed as needed. In addition, a formation position and/or an area of the respective electrode layer may be variously changed.

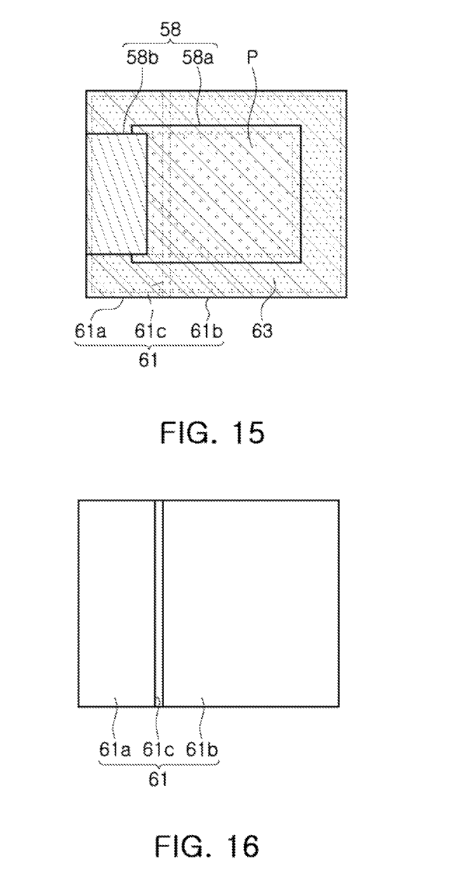

For example, although the first electrode layer 18 illustrated in FIGS. 1 and 2 is illustrated in the form extended along the entirety of the side surface of the semiconductor laminate, the first electrode layer 18 may only be extended on a portion of the side surface of the semiconductor laminate L so as to be connected to the first package electrode 21a (see ‘58b’ of FIG. 15). The second electrode layer 19 may also be appropriately changed according to a shape of the second package electrode 21b.

The support body 21 including the first package electrode 21a and the second package electrode 21b may be disposed on the second surface of the semiconductor laminate L. The first and second package electrodes 21a and 21b may be bonded to the semiconductor laminate L through an insulating film 17 formed on the second surface of the semiconductor laminate L. The insulating film 17 may be formed using a bonding-available material such as a resin, for example, a mixture of silicon oxide, silicon nitride, and a polymer.

As illustrated in FIG. 3, the first and second package electrodes 21a and 21b employed in the exemplary embodiment may be separated from each other by an air gap g. In this case, the second package electrode 21b may be bonded to the insulating film. 17 so as to be fixed to the semiconductor laminate L.

In the exemplary embodiment, although the insulating film 17 is illustrated as having a bonding function, the present disclosure is not limited thereto. The first and second package electrodes 21a and 21b may be bonded to each other using a separate bonding material, besides the insulating film 17. For example, the second package electrode 21b may be bonded to the second electrode layer 19 using a eutectic bonding material such as AuSn and NiSi.

As described above, in the exemplary embodiment, since the second surface of the semiconductor laminate L is not etched for the formation of an electrode for the first conductivity-type semiconductor layer 14, a relatively large step portion may not occur in a junction surface of the semiconductor laminate L, for example, the second surface, and thus, stable junction between the semiconductor laminate L and the support body 21 may be maintained.

As illustrated in FIG. 3, the first package electrode 21a may have a structure encompassing the second package electrode 21b. The first package electrode 21a may be formed to extend to an edge of the semiconductor laminate L. The extended portion may be provided as a contact region C for the connection to the first electrode layer 18.

As illustrated in FIG. 1, the contact region C of the first package electrode 21a may be provided as a descending region located in a position lower than that of the other region. The first electrode layer 18 may be electrically insulated from the side surface of the semiconductor laminate L through the side insulating layer 23 so as to be connected to the first package electrode 21a.

The first and second package electrodes 21a and 21b may serve not only as the unit applying a voltage to the semiconductor laminate L, but also as a path discharging heat generated in the active layer 15 to the outside. According to the exemplary embodiment, since the second electrode layer 19 may be formed over a relatively wide area on the second surface, heat generated in the semiconductor laminate L may be more effectively discharged through the second package electrode 21b. In order to smoothly discharge heat, a region of the second surface in which the second electrode layer 19 is formed may occupy 50% or more of the overall area of the second surface. The second package electrode 21b may have a larger cross sectional area than that of the first package electrode 21a. Here, the cross sectional area refers to an area of a surface of the package electrode obtained by cutting the package electrode in a direction perpendicular to a thickness direction of the package electrode.

The first and second package electrodes 21a and 21b may be formed using a material having excellent electric conductivity and heat conductivity. For example, the first and second package electrodes 21a and 21b may be configured using a semiconductor such as a Si semiconductor or may be formed using Cu, Al, Ag, Au, Ni, Cr, Pd, Cu, Pt, Sn, W, Rh, Ir, Ru, Mg, Zn, or an alloy thereof. The first and second package electrodes 21a and 21b may have a thickness sufficient to be able to support the semiconductor laminate L. For example, the first and second package electrodes 21a and 21b may have a thickness of tens of micrometers or more, for example, 50 μm to 500 μm.

The semiconductor light emitting device package 20 may further include the wavelength conversion layer 26 converting a wavelength of light emitted from the active layer 15. Light converted by the wavelength conversion layer 26 and light emitted by the active layer 15 may be combined to provide light, for example, light having a desired color, such as white light. The wavelength conversion layer 26 may be disposed to cover at least a main emission region, for example, the first surface of the semiconductor laminate L. The wavelength conversion layer 26 may contain a phosphor or a quantum dot, and the wavelength conversion layer 26 may be formed through the mixing thereof with a material such as a transparent resin. In an example, the wavelength conversion layer 26 may be formed through a molding process and a coating process, and may also be formed through a scheme in which a film is first manufactured and then attached.

The semiconductor light emitting device package 20 may include the resin encapsulation unit 27 encompassing the semiconductor laminate L. The resin encapsulation unit 27 may have a lens structure covering the semiconductor laminate L as needed. For example, the resin encapsulation unit 27 may have a dorm shape having a convex upper surface or may have a form in which colloidal particles are disposed on a surface thereof. Such a resin encapsulation unit 27 may be formed using a material having excellent light transmissivity and heat resistance so as to improve light diffusion, and for example, silicone, an epoxy, glass, or a plastic material may be used.

According to the example embodiment, a side of the resin encapsulation unit 27 may have a surface substantially coplanar with a side surface of the support body 21. A portion of the first electrode layer 18 may be disposed between the resin encapsulation unit 27 and the support body 21 and may be exposed to the substantially coplanar side surface.

FIGS. 5 to 13 are cross-sectional views of respective main processes illustrating a method of manufacturing a semiconductor light emitting device package illustrated in FIG. 1, according an exemplary embodiment of the present invention.

As illustrated in FIG. 5, a method of manufacturing a semiconductor light emitting device package may be performed by first preparing a wafer W on which a semiconductor laminate L is formed. A cross-sectional view of the semiconductor laminate L illustrated in FIG. 5 is taken along line A-A′ of a region of the wafer W illustrated in FIG. 4, corresponding to two light emitting devices.

The semiconductor laminate L may include a first conductivity-type semiconductor layer 14, an active layer 15 and a second conductivity-type semiconductor layer 16 formed on a growth substrate 11, as epitaxial layers for a plurality of light emitting devices. As the growth process, a commonly known process such as a metal organic chemical vapor deposition (MOCVD) process, a hydride vapor phase epitaxy (HVPE) process, a molecular beam epitaxy (MBE) process, or the like, may be used.

As the growth substrate 11, an insulating, a conductive or a semiconductor substrate may be used as needed. For example, as the growth substrate 11, a sapphire substrate, a SiC substrate, a Si substrate, a MgAl₂O₄ substrate, a MgO substrate, a LiAlO₂ substrate, a LiGaO₂ substrate, or a GaN substrate may be used.

The semiconductor laminate L may be provided as a nitride semiconductor, and for example, the first and second conductivity-type semiconductor layers 14 and 16 may be formed using a nitride single-crystal material having a composition of AlₓIn_{y}Ga_{1-x-y}N (0≦x≦1, 0≦y≦1, 0≦x+y≦1), but are not limited thereto. For example, an AlGaInP-based semiconductor or an AlGaAs-based semiconductor may be used. The first and second conductivity-type semiconductor layers 14 and 16 may be configured of semiconductors doped with an n-type impurity and a p-type impurity, respectively, but are not limited thereto. For example, conversely, the first and second conductivity-type semiconductor layers 14 and 16 may be provided as a p-type semiconductor layer and an n-type semiconductor layer, respectively. The active layer 15 may have a multiple quantum well (MQW) structure in which quantum well layers and quantum barrier layers are alternately stacked on top of each other, and for example, may have a GaN/InGaN structure in the case of a nitride semiconductor. For example, in the case of the nitride semiconductor, a total of thickness of the semiconductor laminate L may be within a range of 2.5 μm to 10 μm.

The semiconductor laminate L may be formed on a buffer layer 12 formed on the substrate 11. The buffer layer 12 may be used to reduce displacement due to mismatched lattice constants between the substrate 11 and the semiconductor laminate L to be formed in a subsequent process, reduce deformation due to a difference in a thermal expansion coefficient, and suppress occurrence of cracks. The buffer layer 12 may be configured of a single layer and may also have a multiple layer structure having a plurality of layers.

For example, when a silicon substrate is used as the nitride single-crystal growth substrate 11, the (111) plane of silicon may be used as a surface for crystal growth. In this case, the buffer layer 12 may include an AlN nucleation growth layer and a lattice buffer layer configured of a nitride crystal containing Al.

As illustrated in FIG. 6, the second electrode layer 19 connected to the second conductivity-type semiconductor layer 16 may be formed on a portion of an upper surface region, for example, the second surface, of the semiconductor laminate L, and the insulating film 17 may be formed in the other regions. The second electrode layer 19 may be provided in regions for respective separate light emitting devices.

The second electrode layer 19 may be formed on a portion of the upper surface region of the semiconductor laminate L by depositing an ohmic material thereon. The second electrode layer 19 may contain a material such as Ag, Ni, Al, Rh, Pd, Ir, Ru, Mg, Zn, Pt, or Au and may have a two or more layer structure such as Ni/Ag, Zn/Ag, Ni/Al, Zn/Al, Pd/Ag, Pd/Al, Ir/Ag. Ir/Au, Pt/Ag, Pt/Al, Ni/Ag/Pt, or the like, but is not limited thereto. For example, the second electrode layer 19 may be formed using Ag having high reflectivity so as to obtain ohmic contact with the second conductivity-type semiconductor layer 16. Selectively, single layers of Ni, Ti, Pt, and W, or alloy layers thereof may be alternately stacked on such an Ag layer. As a detailed example, a Ni/Ti layer, a TiW/Pt layer, or a Ti/W layer may be stacked, or the Ni/Ti layer, the TiW/Pt layer and the Ti/W layer may be alternately stacked on one another. The second electrode layer 19 may occupy 50% or more of the overall area of the second surface of the semiconductor laminate L.

In this process, the insulating film 17 may also be formed in a different region such as the upper surface of the semiconductor laminate L. The formation process of the insulating film 17 may be performed before or after the second electrode layer 19 is formed. The insulating film 17 may electrically insulate the first package electrode 21a to be located on a lower surface of the semiconductor laminate L from the first conductivity-type semiconductor layer 14. The insulating film 17 may be formed using silicon oxide or silicon nitride. The insulating film 17 may be deposited through a process such as chemical vapor deposition (CVD). The insulating film 17 may be formed using an insulation bonding material such as a polymer resin.

According to the example embodiment, the insulating film 17 may be used as a bonding layer for bonding of the support body. For example, when the insulating film 17 is used as the bonding layer, a polishing process thereon may be performed through a chemical mechanical polishing (CMP) process after the insulating film 17 is deposited, such that surface roughness thereof may be 10 nm or less.

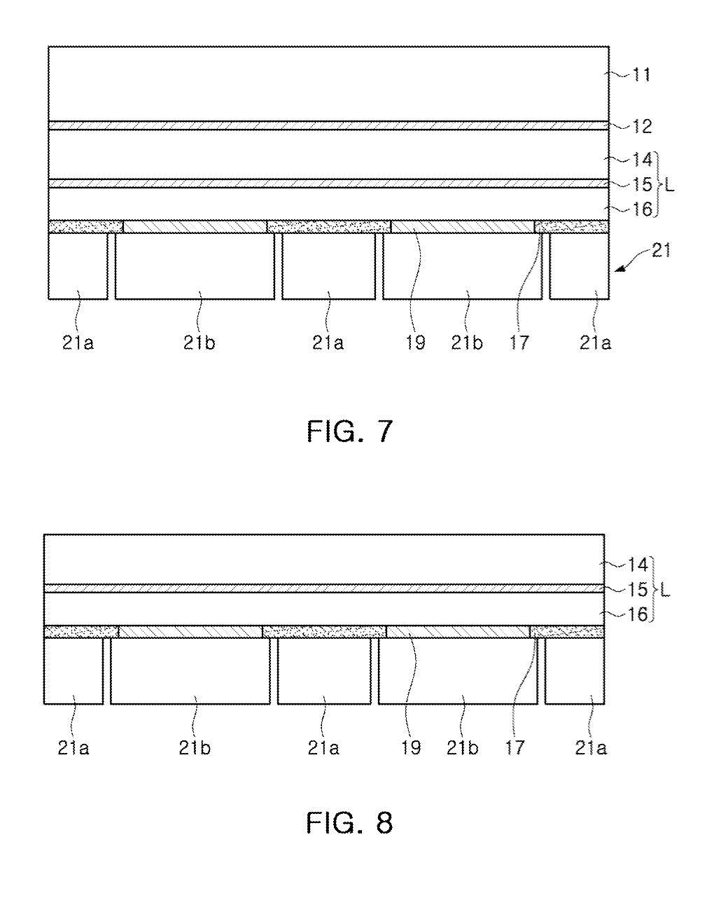

As illustrated in FIG. 7, the support body 21 may be bonded to a lower surface, for example, the second surface, of the semiconductor laminate L.

The support body 21 used in this process may include a plurality of first and second package electrodes 21a and 21b corresponding to respective device regions of the semiconductor laminate L. The support body may be bonded to the insulating film 17. For example, the support body 21, for example, formed of Si, may be directly bonded to the insulating film or may be bonded thereto using an oxide-oxide bonding or oxide-silicon bonding technology at a relatively low temperature, for example, 500° C. or lower, after forming an oxide layer on the support body 21. In this case, the first package electrode 21a may be located on the insulating film 17 to be bonded thereto, and a portion of the second package electrode 21b may also be located on the insulating film 17 to be bonded thereto.

On the other hand, the support body 21 may be bonded using a separate bonding material, besides the insulating film 17. As the separate bonding material, a eutectic metal such as a polymer resin, AuSn, or NiSi may be used. For example, the second package electrode 21b may be bonded to the second electrode layer 19 using a conductive bonding material such as a eutectic metal.

As a detailed example, a mask through which a region in which the first and second package electrodes 21a and 21b are to be formed is exposed may be formed on a lower surface of the semiconductor laminate L, and then, the first and second package electrodes 21a and 21b may be formed using electroplating or sputtering. The first and second package electrodes 21a and 21b may be formed using Cu, Al, Ag, Au, Ni, Cr, Pd, Cu, Pt, Sn, W, Rh, Ir, Ru, Mg, or Zn, or using an alloy thereof. For example, a material having excellent electric conductivity and thermal conductivity and facilitating the electroplating process may be used.

As necessary, before or after the formation of the mask, a diffusion prevention layer (a barrier layer) and/or a seed layer transferring a current at the time of performing electroplating may be formed. The diffusion prevention layer and/or the seed layer may be configured of a Ti layer/a Cu layer using a sputtering process, and a thickness of a respective layer thereof may be in a range of 50 nm to 500 nm. The remaining portions of the first and second package electrodes 21a and 21b may be formed through the electroplating process after the formation of the diffusion prevention layer and/or the seed layer. A Cu/Ni/Au layer in which a thickness of a respective layer thereof is in a range of 0.01 μm to 50 μm may be formed. After forming the first and second package electrodes 21a and 21b, the mask may be removed.

As illustrated in FIG. 8, the growth substrate 11 may be removed from the semiconductor laminate L.

The removal process may be performed using a laser lift-off process or a mechanical polishing process, and an etching process. In a case in which the growth substrate 11 is formed of a transparent material such as sapphire, the growth substrate 11 may be removed through the laser lift-off process in which laser is irradiated onto the vicinity of an interface between the semiconductor laminate L and the growth substrate 11. In a case in which the growth substrate 11 is a silicon substrate having a relatively low degree of hardness, the growth substrate may be removed through a mechanical polishing process or a wet or dry etching process.

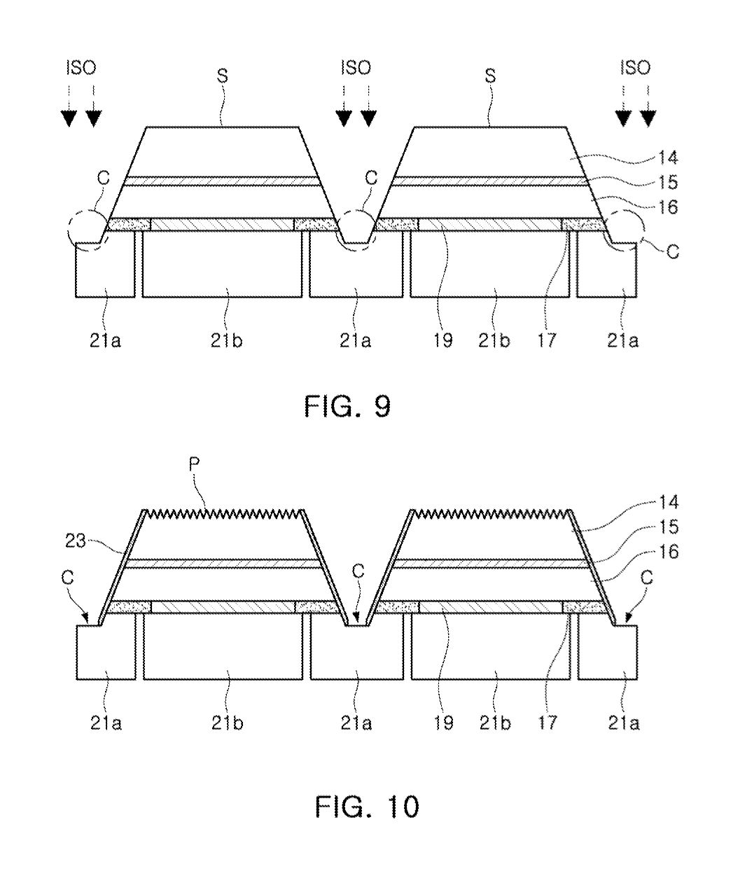

As illustrated in FIG. 9, a separation process (ISO) of dividing the semiconductor laminate L into individual light emitting device regions S may be performed.

The semiconductor laminate L may be divided into the individual semiconductor light emitting device regions S through a selective removal process. Such a separation process may be performed through a mechanical cutting process, a chemical etching process, or a dry etching process using plasma.

In this process, regions between the semiconductor light emitting device regions S may be removed, such that the first package electrode 21a may be partially exposed therethrough. To this end, when the support body 21 is provided with the semiconductor laminate L, the support body 21 may be located in a position from which portions of the first package electrode 21a are to be selectively removed. In a subsequent process, the exposed regions of the first package electrode 21a may be provided as contact regions C for a connection to the first conductivity-type semiconductor layer 14. Since the contact regions C may be obtained through the separation process, the contact regions may be provided as descending regions sunk to be lower than a level of the remaining region of the upper surface of the first package electrode 21a. As the contact regions C are provided as the descending regions, a connection area may be increased.

As illustrated in FIG. 10, a side insulating layer 23 may be formed on the side surface of the semiconductor laminate L. In addition, a concave-convex portion P may be formed in an upper surface of the semiconductor laminate L.

The side insulating layer 23 may be formed in a scheme of forming an insulating layer on the entire surface of the separated semiconductor laminate L and then exposing the contact regions of the first package electrode 21a and the upper surface of the semiconductor laminate L.

The concave-convex portion P for improvement of light extraction efficiency may be formed in an upper surface of the first conductivity-type semiconductor layer 14. The concave-convex formation process may be performed during the removal process of the substrate or may also be performed thereafter. The concave-convex portion P may be formed through a mechanical process, a wet etching process or a dry etching process using plasma.

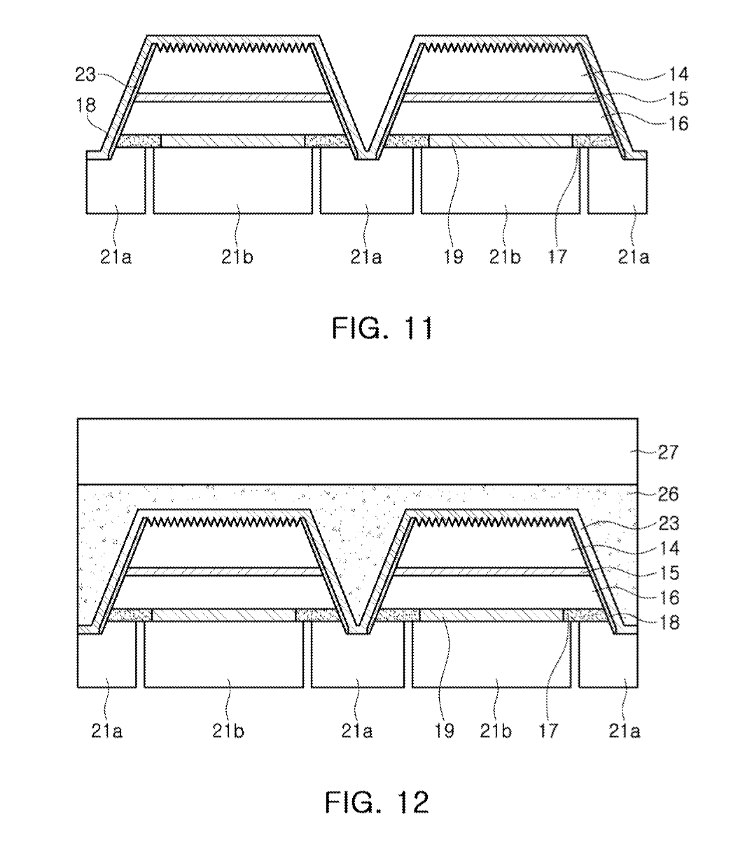

As illustrated in FIG. 11, the first electrode layer 18 may be formed to connect the first conductivity-type semiconductor layer 14 disposed on an upper surface of the semiconductor laminate L to the first package electrode 21a.

The first electrode layer 18 may be extended along the entirety of the side surface of the semiconductor laminate L to be connected to the contact region C of the first package electrode 21a. The first electrode layer 18 may include a transparent electrode. In the exemplary embodiment, although the entirety of the first electrode layer 18 may be configured of a transparent electrode, applications thereof may be variously performed. The transparent electrode may be configured of one of a transparent conductive oxide layer and nitride layer, but is not limited thereto. For example, the transparent electrode may be formed using at least one selected from a group consisting of ITO, ZITO, ZIO, GIO, ZTO, FTO, AZO, GZO, In₄Sn₃O₁₂ and Zn₍₁₋ₓ₎MgₓO (0≦x≦1). The first electrode layer 18 may contain graphene as needed.

As illustrated in FIG. 12, the wavelength conversion layer 26 and the resin encapsulation unit 27 may be sequentially formed on the semiconductor laminate L.

The wavelength conversion layer 26 may contain an oxide-based phosphor, a silicate-based phosphor, a nitride-based phosphor, a sulfide-based phosphor and a fluoride-based phosphor, but is not limited thereto. In the case of an oxide-based material, yellow and green phosphors, (Y, Lu, Se, La, Gd, Sm)₃(Ga, Al)₅O₁₂:Ce, a blue phosphor, BaMgAl₁₀O₁₇:Eu, 3Sr₃(PO₄)₂—CaCl:Eu, and the like, may be used. In the case of a silicate-based material, yellow and green phosphors, (Ba, Sr)₂SiO₄:Eu, and yellow and orange phosphors, (Ba, Sr)₃SiO₅:Eu, and the like, may be used. In addition, in the case of a nitride-based material, a green phosphor, β-SiAlON:Eu, a yellow phosphor, (La, Gd, Lu, Y, Sc)₃Si₆N₁₁:Ce, an orange phosphor, α-SiAlON:Eu, red phosphors, (Sr, Ca)AlSiN₃:Eu, (Sr, Ca)AlSi(ON)₃:Eu, (Sr, Ca)₂Si₅N₈:Eu, (Sr, Ca)₂Si₅(ON)₈:Eu, (Sr, Ba)SiAl₄N₇:Eu, and the like, may be used. In the case of a sulfide-based material, a red phosphor, (Sr, Ca)S:Eu, (Y, Gd)₂O₂S:Eu, a green phosphor, SrGa₂S₄:Eu, and the like, may be used. In the case of a fluorine-based material, a red phosphor, K₂SiF₆:Mn⁴⁺ may be used. In addition, as a phosphor substitute, materials such as a quantum dot (QD) and the like may be applied, and a phosphor and QD may be used as a combination thereof or alone in an LED. For example, QD may have a structure including a core of CdSe, InP, or the like of 3 to 10 nm, a shell of ZnS, ZnSe, or the like of 0.5 to 2 nm, and a ligand for stabilization of the core and the shell. The wavelength conversion layer 26 may be formed using at least one of a spraying process, a dispensing process, and a process of bonding a phosphor-containing resin sheet or a ceramic phosphor sheet.

Subsequently, the resin encapsulation unit 27 may be formed on the wavelength conversion layer 26. The resin encapsulation unit 27 may have a lens structure covering the semiconductor laminate L as needed. For example, the resin encapsulation unit 27 may have a dorm-shaped structure having a convex upper surface or may have a form in which colloidal particles are disposed on a surface thereof so as to improve light diffusion. Such a resin encapsulation unit 27 may be formed using a material having excellent light transmissivity and heat resistance, and for example, silicone, an epoxy, glass, or a plastic material may be used.

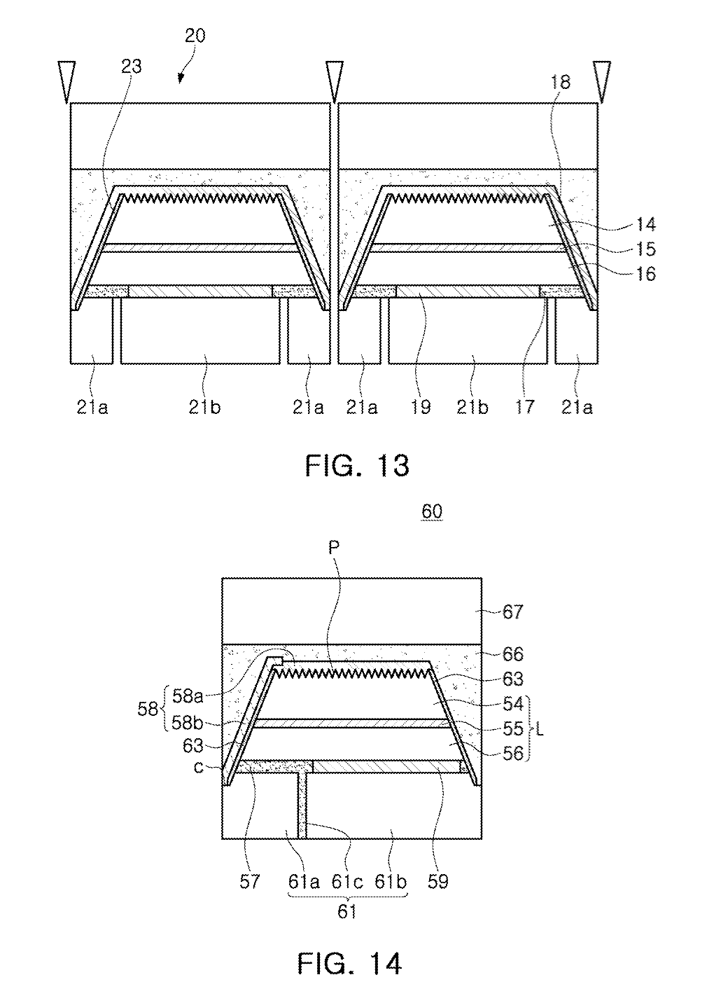

As illustrated in FIG. 13, a resultant object illustrated in FIG. 12 may be divided into the units corresponding to semiconductor light emitting device packages 20.

By performing the process of separation into the semiconductor light emitting device package units, as a result, the semiconductor light emitting device package 20 illustrated in FIG. 1 may be obtained. The separation process may be performed through blade cutting or laser cutting. The separation process may be applied in the cutting process of the supply body 21.

In the semiconductor light emitting device package 20 illustrated in FIG. 13, a side of the resin encapsulation unit 27 may have a surface substantially coplanar with a side surface of the support body 21. A portion of the first electrode layer 18 may be disposed between the resin encapsulation unit 27 and the support body 21 and may be exposed to the substantially flat coplanar surface.

The present disclosure may be implemented through various embodiments. For example, a material of the first electrode layer, a formation position thereof, and a structure of the support body may be variously changed. Embodiments thereof will be described with reference to FIGS. 14 to 16.

FIG. 14 is a cross-sectional view schematically illustrating a semiconductor light emitting device package according to another exemplary embodiment of the present invention, and FIGS. 15 and 16 are a top plan view and a bottom view of a semiconductor light emitting device package of FIG. 14, respectively.

With reference to FIG. 14, a semiconductor light emitting device package 60 according to an example embodiment may include a semiconductor laminate L, a support body 61, a wavelength conversion layer 66 encompassing the semiconductor laminate L, and a resin encapsulation unit 67. The semiconductor light emitting device package 60 according to the example embodiment may be a chip scale package (CSP).

The semiconductor laminate L may include a first conductivity-type semiconductor layer 54, a second conductivity-type semiconductor layer 56, and an active layer 55 disposed therebetween. The semiconductor laminate L may have a first surface and a second surface provided by the first and second conductivity-type semiconductor layers 54 and 56, respectively, and side surfaces disposed therebetween.

The semiconductor laminate L may be a nitride semiconductor satisfying AlₓIn_{y}Ga_{1-x-y}N (0≦x≦1, 0≦y≦1, and 0≦x+y≦1). The first and second conductivity-type semiconductor layers 54 and 56 configuring the semiconductor laminate L may be a p-type semiconductor layer and an n-type semiconductor layer, respectively. For example, the first conductivity-type semiconductor layer 54 may be an n-type GaN layer, and the second conductivity-type semiconductor layer 56 may be a p-type AlGaN/p-type GaN layer. The active layer 55 may have a multiple quantum well (MQW) structure in which quantum well layers and quantum barrier layers are alternately stacked on top of each other. For example, the active layer 55 may have a multiple quantum well structure of GaN/InGaN.

A side insulating layer 63 may be formed on the side surface of the semiconductor laminate L. As illustrated in FIGS. 13 and 14, the side insulating layer 63 may be disposed on the entirety of the side surface of the semiconductor laminate L to be provided as a passivation layer thereon. For example, the side insulating layer 63 may be a silicon oxide layer or a silicon nitride layer. The side surface of the semiconductor laminate L may be provided as an inclined plane.

According to the example embodiment, a first electrode layer 58 and a second electrode layer 59 may be connected to the first conductivity-type semiconductor layer 54 and the second conductivity-type semiconductor layer 56 through the first surface and the second surface of the semiconductor laminate L, respectively. As such, since two electrodes 58 and 59 are disposed on the first and second surfaces of the semiconductor laminate, respectively, a relatively high degree of uniform current distribution may be promoted on the semiconductor laminate L, in detail, in terms of the overall area of the active layer.

In the exemplary embodiment, the first electrode layer 58 connected to the first conductivity-type semiconductor layer 54 on the first surface of the semiconductor laminate L may be extended along the side surface of the semiconductor laminate L and may be connected to the first package electrode 61a disposed on the second surface. In the example embodiment, unlike the cases of the example embodiments described with reference to FIGS. 1 and 2, the first electrode layer 58 may be extended along one of four sides of the semiconductor laminate to be connected to the first package electrode 61a. As such, the first electrode layer 58 may have a form extended along a portion of the side surface of the semiconductor laminate.

The first electrode layer 58 may include a transparent electrode so as to secure light transmissivity. In the case of the first electrode layer 58 employed in the exemplary embodiment, a portion thereof located on the first surface corresponding to a main light emission surface may be configured of a transparent electrode 58a and the remaining region thereof may be configured of a metal electrode 58b as illustrated in FIG. 15.

According to the embodiment in the present disclosure, the first and second package electrodes 61a and 61b may be connected to the first and second electrode layers 58 and 59, respectively. As illustrated in FIG. 14, the first package electrode 61a may have a contact region C for a connection thereof to the first electrode layer 58 in a portion thereof located on an edge of the semiconductor laminate L. The contact region C of the first package electrode 61a may be provided as a descending region to be lower than a level of an upper surface of the remaining region thereof. The first electrode layer 58 may be electrically insulated from the side surface of the semiconductor laminate L by the side insulating layer 63 and may be connected to the first package electrode 61a.

The second electrode layer 59 may be formed on the second surface of the semiconductor laminate L. The second electrode layer 59 may be formed using an ohmic contact material having a relatively high degree of reflectivity.

The support body 61 may be disposed on the second surface of the semiconductor laminate L. As illustrated in FIG. 15, the support body 61 may include the first package electrode 61a and the second package electrode 61b disposed to be parallel to each other and an insulator 61c disposed between the first and second package electrodes 61a and 61b to connect the two electrodes 61a and 61b to each other. The insulator 61c may be formed using a bonding material having electrical insulation properties. For example, the insulator 61c may be formed using an electrically insulating material such as a silicon oxide, a silicon nitride or a polymer resin.

The first and second package electrodes 61a and 61b may serve as discharging heat generated in the semiconductor laminate L. According to the example embodiment, the second electrode layer 59 and the second package electrode 61b may be formed so that cross sectional areas thereof may be relatively increased, to effectively discharge heat generated from the semiconductor laminate L through the second package electrode 61b.

The first and second package electrodes 61a and 61b may be bonded to the semiconductor laminate L by an insulating film 57 formed on the second surface of the semiconductor laminate L. The insulating film 57 may be formed using a bonding-available material, for example, a silicon oxide, a silicon nitride, or resins such as a polymer.

The semiconductor light emitting device package 60 may further include a wavelength conversion layer 66 converting a wavelength of light emitting from the active layer 55. Light converted by the wavelength conversion layer 66 and light emitted by the active layer 55 may be combined to provide light, for example, light having a desired color, such as white light. The semiconductor light emitting device package 60 may further include a resin encapsulation unit 67 encompassing the semiconductor laminate L.

According to the exemplary embodiment, a side of the resin encapsulation unit 67 may have a surface substantially coplanar with a side surface of the support body 61. A portion of the first electrode layer 58 may be disposed between the resin encapsulation unit 67 and the support body 61 and may be exposed to the substantially coplanar surface.

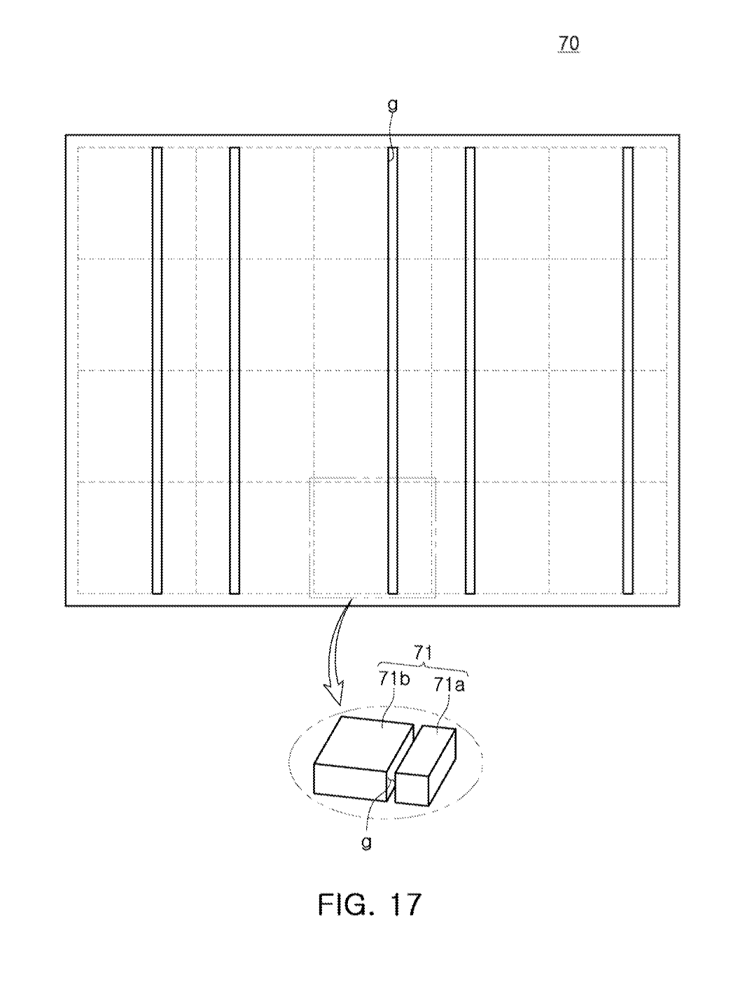

FIG. 17 is a schematic view of a support body employed in a semiconductor light emitting device package according to an example embodiment.

A support body array 70 illustrated in FIG. 17 may include a support body for formation of a plurality of packages. The support body array 70 according to the exemplary embodiment may have a 5×4 array, but actually, may be provided in a form corresponding to respective light emitting device regions S on the wafer W illustrated in FIG. 4. In the support body array 70, a first package electrode 71a and a second package electrode 71b may be separated from each other by an air gap (g) extended in a single direction.

The support body array 70 may have the form (see FIG. 4) provided with the semiconductor laminate L at a wafer level. After bonding of the support body array to the semiconductor laminate at the wafer level, an electrode formation process thereof may be performed and a process of cutting thereof into package units may be performed to divide the support body array 70 into support bodies 71 corresponding to individual package units (see FIG. 13). The support body 71 may include first and second package electrodes 71a and 71b arrayed in parallel to each other similarly to the support body 61 illustrated in FIG. 15 and may have a form in which they are separated from each other through an air gap (g). The respective first and second package electrodes 71a and 71b may be bonded to the semiconductor laminate. The support body array 70 may be configured using a semiconductor such as a Si semiconductor or using a material such as Cu, Al, Ag, Au, Ni, Cr, Pd, Cu, Pt, Sn, W, Rh, Ir, Ru, Mg, Zn, or an alloy thereof.

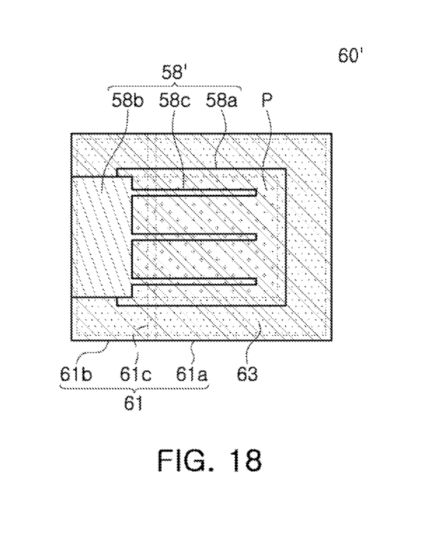

FIG. 18 is a top plan view of a semiconductor light emitting device package according to an exemplary embodiment of the present invention.

A semiconductor light emitting device package 60′ according to the example embodiment may have a structure similar to that of the semiconductor light emitting device package 60 illustrated in FIG. 14. For example, a first electrode layer 58′ may be extended to a portion of the side surface of a semiconductor laminate to be connected to a first package electrode 61a. However, unlike the foregoing example embodiment, the first electrode layer 58′ illustrated in FIG. 18 may further include three electrode fingers 58c disposed on a transparent electrode layer 58a located on an upper surface of a first conductivity-type semiconductor layer. The three electrode fingers 58c may be extended from a metal electrode layer 58b so as to uniformly distribute a current in the overall region of the transparent electrode layer 58a. The three electrode fingers 58c of FIG. 18 are for the purpose of illustration, but the present invention is not limited thereto.

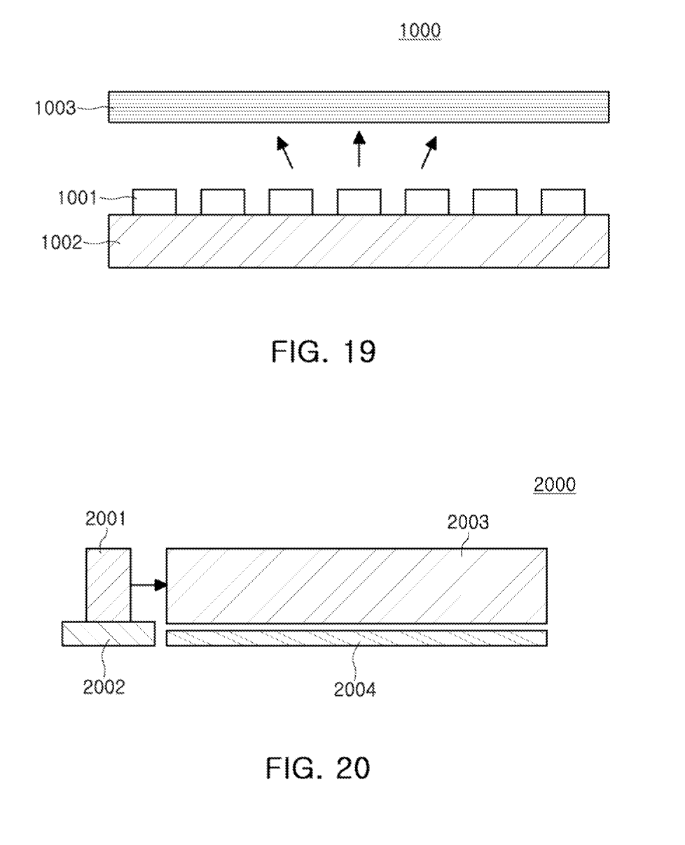

FIGS. 19 and 20 illustrate examples of a backlight unit to which a semiconductor light emitting device package according to an example embodiment is applied.

With reference to FIG. 19, a back light unit 1000 may include a light source 1001 mounted on a substrate 1002 and one or more optical sheets 1003 disposed thereabove. As the light source 1001, the semiconductor light emitting device package having the structure described above according to any one of the foregoing example embodiments or a semiconductor light emitting device package having a structure similar thereto may be used. For example, first and second package electrodes of the semiconductor light emitting device package described above according to any one of the foregoing example embodiments may be connected to an electrode pattern of the substrate 1002.

In the backlight unit 1000 of FIG. 19, the light source 1001 emits light upwardly in a direction in which a liquid crystal display device is disposed, while in a backlight unit 2000 of another example illustrated in FIG. 20, a light source 2001 mounted on a substrate 2002 emits light in a lateral direction such that the emitted light may be incident onto a light guiding panel 2003 to be converted into a form of surface light source type light. Light passing through the light guiding panel 2003 may be discharged in an upward direction, and a reflective layer 2004 may be disposed below the light guiding panel 2003 to improve light extraction efficiency.

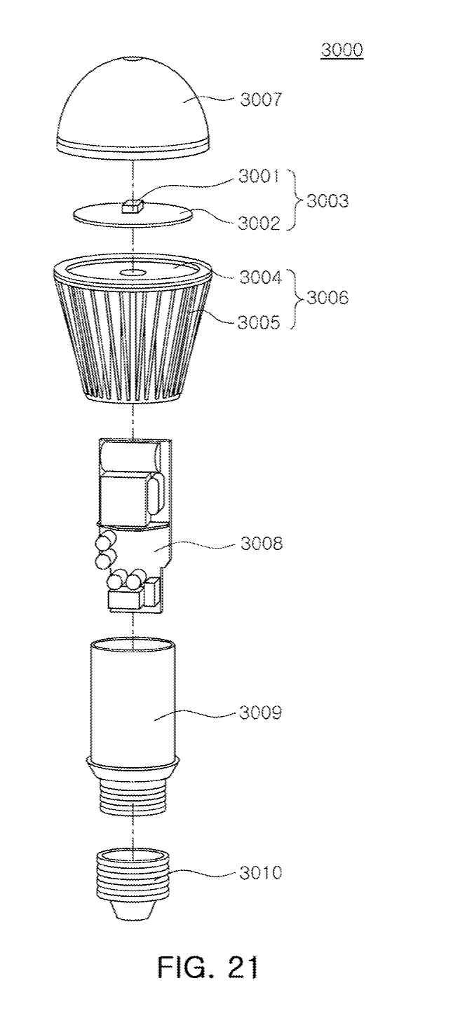

FIG. 21 is an exploded perspective view illustrating an example of a lighting device in which a semiconductor light emitting device package according to an example embodiment is employed.

A lighting device 3000 illustrated in FIG. 21 is illustrated as being a bulb type lamp by way of example. The lighting device 3000 may include a light emitting module 3003, a driving unit 3008, and an external connection unit 3010.

In addition, the lighting device 3000 may further include a structure of appearance such as external and internal housings 3006 and 3009 and a cover unit 3007. The light emitting module 3003 may include a light source 3001 having the semiconductor light emitting device package structure described above according to any one of the foregoing example embodiments or a structure similar thereto, and a circuit board 3002 on which the light source 3001 is mounted. For example, the first and second package electrodes of the semiconductor light emitting device package described above according to any one of the foregoing example embodiments may be connected to an electrode pattern of the circuit board 3002. Although the example embodiment illustrates the case in which a single light source 3001 is mounted on the circuit board 3002, a plurality of light sources may be mounted on the circuit board 3002 as needed.

The external housing 3006 may serve as a heat radiating unit, and the external housing 3006 may include a heat radiating plate 3004 directly contacting the light emitting module 3003 to improve a heat radiation effect, and heat radiating fins 3005 disposed to encompass a side of the lighting device 3000. The cover unit 3007 may be installed on the light emitting module 3003 and may have a convexly formed lens shape. The driving unit 3008 may be installed in the internal housing 3009 to be connected to the external connection unit 3010 having a structure such as a socket structure so as to receive power from an external power supply. In addition, the driving unit 3008 may convert the received power into a current source suitable for driving the semiconductor light emitting device 3001 of the light emitting module 3003 to then be supplied. For example, the driving unit 3008 may be configured of an AC to DC converter, a rectifying circuit component, or the like.

Although not illustrated in the drawings, the lighting device 3000 may also further include a communications module.

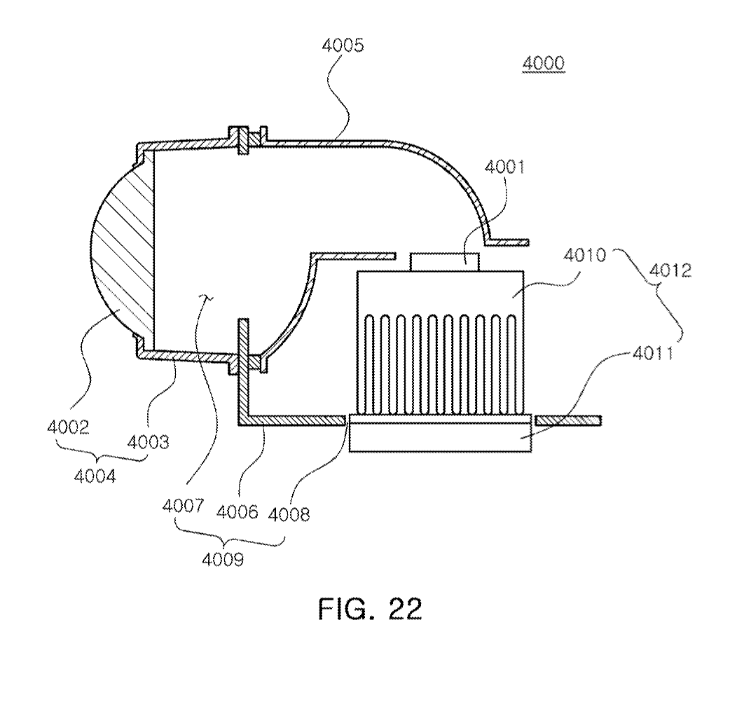

FIG. 22 illustrates an example to which a semiconductor light emitting device package according to an example embodiment is applied.

With reference to FIG. 22, a headlamp 4000 for vehicle lighting or the like may include a light source 4001, a reflective unit 4005 and a lens cover unit 4004, and the lens cover unit 4004 may include a hollow guide 4003 and a lens 4002. The light source 4001 may include at least one semiconductor light emitting device package having the semiconductor light emitting device package structure described above according to any one of the foregoing example embodiments or a structure similar thereto.

The headlamp 4000 may further include a heat radiating unit 4012 discharging heat generated in the light source 4001 to the outside. The heat radiating unit 4012 may include a heat sink 4010 and a cooling fan 4011 to perform effective heat emissions. In addition, the headlamp 4000 may further include a housing 4009 fixing and supporting the heat radiating unit 4012 and the reflective unit 4005, and the housing 4009 may have a central hole 4008 in one surface thereof, to facilitate coupling of the heat radiating unit 4012 thereto and mounting thereof.

The housing 4009 may have a front hole 4007 in the other surface integrally connected to the one surface to then be bent in a direction orthogonal thereto, through which the reflective unit 4005 is fixed to be disposed over the light source 4001. Whereby, the front side thereof may be open by the reflective unit 4005, and the reflective unit 4005 may be fixed to the housing 4009 such that the open front side corresponds to the front hole 4007, such that light reflected through the reflective unit 4005 may pass through the front hole 4007 to be then emitted externally.

According to the example embodiments, a process of forming electrodes, for example, an n-side electrode may be simplified by respectively disposing two electrodes on two surfaces of a semiconductor laminate opposing each other. For example, an etching process of a semiconductor laminate for formation of an electrode or a process of forming a through electrode such as a through silicon via (TSV) may be omitted.

Since the occurrence of a step portion in an insulating film disposed on a junction surface of a semiconductor laminate, for example, a second surface, may be reduced, a relatively high degree of bonding strength between a chip wafer and a support body may be secured.

Since two electrodes are arrayed to be perpendicular to each other, current dispersion efficiency may be increased, and further, since a light emission area is not decreased in an electrode formation process, light emission efficiency may be further improved. In addition, a contact area between a chip electrode and a package electrode may be increased and thus, heat radiation performance may be improved.

While embodiments have been shown and described above, it will be apparent to those skilled in the art that modifications and variations could be made without departing from the scope of the present disclosure as defined by the appended claims.

1. A semiconductor light emitting device package, comprising:
a semiconductor laminate having a first surface and a second surface disposed opposite to each other, and a side surface connecting the first and second surfaces, and including a first conductivity-type semiconductor layer and a second conductivity-type semiconductor layer forming the first surface and the second surface, respectively, and an active layer disposed between the first and second conductivity-type semiconductor layers;
a support body disposed on the second surface of the semiconductor laminate and including a first package electrode and a second package electrode;
a first electrode layer disposed on the first surface of the semiconductor laminate to be connected to the first conductivity-type semiconductor layer and extending along the side surface of the semiconductor laminate to be connected to the first package electrode;
a side insulating layer disposed on the side surface of the semiconductor laminate and electrically insulating the first electrode layer from the side surface of the semiconductor laminate; and
a second electrode layer disposed between the second surface of the semiconductor laminate and the second package electrode and electrically connecting the first conductivity-type semiconductor layer to the second package electrode.

2. The semiconductor light emitting device package of claim 1, wherein the first package electrode has a contact region located on an edge of the support body, and the contact region is connected to the first electrode layer.

3. The semiconductor light emitting device package of claim 2, wherein the contact region comprises a descending part descending to be lower than a level of another part of the first package electrode.

4. The semiconductor light emitting device package of claim 2, wherein the first package electrode encompasses at least a portion of the second package electrode.

5. The semiconductor light emitting device package of claim 2, wherein the first package electrode and the second package electrode are arrayed to be substantially parallel to each other.

6. (canceled)

7. The semiconductor light emitting device package of claim 1, wherein a cross sectional area of the second package electrode is greater than that of the first package electrode.

8. The semiconductor light emitting device package of claim 1, further comprising an insulating film disposed at least in a region, in which the second electrode layer is not formed, among the second surface of the semiconductor laminate.

9. (canceled)

10. The semiconductor light emitting device package of claim 1, wherein the side surface of the semiconductor laminate has an inclined plane.

11. The semiconductor light emitting device package of claim 1, further comprising a resin encapsulation unit encompassing the semiconductor laminate.

12. The semiconductor light emitting device package of claim 11, wherein a side of the resin encapsulation unit has a surface substantially coplanar with a side surface of the support body.

13. The semiconductor light emitting device package of claim 11, wherein a portion of the first electrode layer is disposed between the resin encapsulation unit and the support body and is exposed to the surface substantially coplanar with the side of the support body.

14. The semiconductor light emitting device package of claim 1, further comprising a wavelength conversion layer disposed on at least the first surface of the semiconductor laminate.

15. The semiconductor light emitting device package of claim 1, wherein the first electrode layer comprises a transparent electrode layer.

16. The semiconductor light emitting device package of claim 1, wherein the first electrode layer comprises a transparent electrode layer disposed on the first surface of the semiconductor laminate and a metal electrode layer disposed along the side surface of the semiconductor laminate to connect the transparent electrode layer and the first package electrode to each other.

17. (canceled)

18. A semiconductor light emitting device package, comprising:
a semiconductor laminate having a first surface and a second surface disposed opposite to each other, and a side surface connecting the first and second surfaces, and including a first conductivity-type semiconductor layer and a second conductivity-type semiconductor layer forming the first surface and the second surface, respectively, and an active layer disposed between the first and second conductivity-type semiconductor layers;
a second electrode layer disposed on a first region of the second surface of the semiconductor laminate and connected to the second conductivity-type semiconductor layer;
an electrically insulating film disposed on a second region of the second surface of the semiconductor laminate;
a first package electrode disposed on the electrically insulating film and having a contact region adjacent to an edge of the second surface of the semiconductor laminate;
a second package electrode disposed on the second surface of the semiconductor laminate and connected to the second electrode layer; and
a first electrode layer connecting the first conductivity-type semiconductor layer to the contact region of the first package electrode.

19. The semiconductor light emitting device package of claim 18, wherein the contact region comprises a descending part descending to be lower than a level of another part of the first package electrode.

20. (canceled)

21. The semiconductor light emitting device package of claim 18, wherein a portion of the second package electrode contacts the electrically insulating film.

22. The semiconductor light emitting device package of claim 18, further comprising an insulating member disposed between the first and second package electrodes to combine the first and second package electrodes to each other.

23. The semiconductor light emitting device package of claim 18, further comprising a resin encapsulation unit encompassing the semiconductor laminate, a side of the resin encapsulation unit having a surface substantially coplanar with side surfaces of the first and second package electrodes.

24. A lighting device, comprising:
the semiconductor light emitting device package of claim 1;
a driving unit driving the semiconductor light emitting device package; and
an external connection unit supplying an external voltage to the driving unit.

25-36. (canceled)
